(19) United States
(12) Patent Application Publication
(10) Pub. No.: US 2022/0399244 A1
(43) Pub. Date: Dec. 15, 2022

(54) THERMALLY CONDUCTIVE AND ELECTRICALLY INSULATING SUBSTRATE

(71) Applicant: AMULAIRE THERMAL TECHNOLOGY, INC., New Taipei City (TW)

(72) Inventors: CHING-MING YANG, New Taipei City (TW); SHIH-HSI TAI, New Taipei City (TW); TZE-YANG YEH, New Taipei City (TW)

(21) Appl. No.: 17/343,745

(22) Filed: Jun. 10, 2021

(51) Int. Cl. H01L 23/367; H01L 23/373; H01L 23/14

(52) U.S. Cl. CPC H01L 23/3672; H01L 23/3735; H01L 23/145

(57) ABSTRACT

A thermally conductive and electrically insulating substrate is provided. The thermally conductive and electrically insulating substrate includes a thermally conductive base, an electrically insulating layer, and one or more metal sheets. The electrically insulating layer is disposed on the thermally conductive base, and the one or more metal sheets are disposed on the electrically insulating layer. The metal sheet is allowed to have one or more chips arranged thereon, and a surface of the metal sheet where the metal sheet is allowed to be engaged with the chip is not parallel to a surface of the electrically insulating layer where the electrically insulating layer is mated with the metal sheet.

### FIELD OF THE DISCLOSURE

The present disclosure relates to a substrate, and more particularly to a thermally conductive and electrically insulating substrate.

### BACKGROUND OF THE DISCLOSURE

Power chips in a power module of current electrical/hybrid vehicles operate on high power, and therefore need to be disposed on thermally conductive and electrically insulating substrates for heat dissipation.

However, referring to FIG. 1, a metal sheet 30A of a conventional thermally conductive and electrically insulating substrate is disposed on an electrically insulating layer 20A in a manner that is parallel to a surface of a substrate 10A or a heat radiator. Accordingly, a plurality of chips 300 cannot be arranged on the metal sheet 30A of the thermally conductive and electrically insulating substrate, which results in a poor utilization rate of the thermally conductive and electrically insulating substrate.

### SUMMARY OF THE DISCLOSURE

In response to the above-referenced technical inadequacy, the present disclosure provides a thermally conductive and electrically insulating substrate.

In one aspect, the present disclosure provides a thermally conductive and electrically insulating substrate that includes a thermally conductive base, an electrically insulating layer, and one or more metal sheets. The electrically insulating layer is disposed on the thermally conductive base, and the one or more metal sheets are disposed on the electrically insulating layer. The metal sheet is allowed to have one or more chips arranged thereon, and at least a part of a surface of the metal sheet where the metal sheet is allowed to be engaged with the chip is not parallel to a surface of the electrically insulating layer where the electrically insulating layer is mated with the metal sheet.

In certain embodiments, the surface of the metal sheet where the metal sheet is allowed to be engaged with the chip and the surface of the electrically insulating layer where the electrically insulating layer is mated with the metal sheet are perpendicular to each other.

In certain embodiments, the surface of the metal sheet where the metal sheet is allowed to be engaged with the chip and the surface of the electrically insulating layer where the electrically insulating layer is mated with the metal sheet have an acute included angle therebetween.

In certain embodiments, the surface of the metal sheet where the metal sheet is allowed to be engaged with the chip and the surface of the electrically insulating layer where the electrically insulating layer is mated with the metal sheet have an obtuse included angle therebetween.

In certain embodiments, a width of a first metal sheet of the metal sheets is different from a width of a second metal sheet of the metal sheets, and a quantity of the chips allowed to be disposed on the second metal sheet is greater than a quantity of the chips allowed to be disposed on the first metal sheet.

In certain embodiments, distances between the metal sheets are different. In certain embodiments, one end of the metal sheet is inserted into the electrically insulating layer.

In certain embodiments, one end of the metal sheet is embedded within the electrically insulating layer.

In certain embodiments, one end of the metal sheet is in an L-shape and is engaged with the electrically insulating layer.

In certain embodiments, one end of the metal sheet is in an inverted T-shape and is engaged with the electrically insulating layer.

In certain embodiments, a thermally conductive layer is formed on the surface of the metal sheet, and the thermally conductive layer is made of graphite or graphene.

In certain embodiments, the metal sheets that are adjacent to each other have an electrically insulating mold arranged therebetween.

In certain embodiments, the electrically insulating mold is made of a high-binding polymer material.

In certain embodiments, the electrically insulating mold is made of a non-metallic material with low electrical conductivity, and the electrically insulating mold has a polymer layer that is attached to a surface of the electrically insulating mold.

In another aspect, the present disclosure provides a thermally conductive and electrically insulating substrate that includes a thermally conductive base, an electrically insulating layer, and at least one metal sheet. The electrically insulating layer is disposed on the thermally conductive base, and the at least one metal sheet is disposed on the electrically insulating layer. The metal sheet has at least one chip arranged thereon, and at least a part of a surface of the metal sheet where the metal sheet is engaged with the chip is not parallel to a surface of the electrically insulating layer where the electrically insulating layer is mated with the metal sheet.

In certain embodiments, the metal sheet is a metal sheet with pre-soldered chips and lead wires.

In certain embodiments, a width of a first metal sheet of the metal sheets is different from a width of a second metal sheet of the metal sheets, and a quantity of the chips disposed on the second metal sheet is greater than a quantity of the chips disposed on the first metal sheet.

In certain embodiments, the metal sheets that are adjacent to each other have an electrically insulating mold arranged therebetween.

In yet another aspect, the present disclosure provides a thermally conductive and electrically insulating substrate that includes a thermally conductive base, an electrically insulating layer, and one or more metal sheets. The electrically insulating layer is disposed on the thermally conductive base, and the one or more metal sheets are disposed on the electrically insulating layer. The metal sheet is bent downwardly, so that a hollow structure is formed between the metal sheet and the electrically insulating layer, the metal sheet has one or more chips arranged thereon, and a surface of the metal sheet where the metal sheet is engaged with the chip is parallel to a surface of the electrically insulating layer where the electrically insulating layer is mated with the metal sheet.

In certain embodiments, the hollow structure has a flowing working fluid therein.

Therefore, by virtue of “at least a part of the surface of the metal sheet where the metal sheet is allowed to be engaged with the chip being not parallel to the surface of the electrically insulating layer where the electrically insulating layer is mated with the metal sheet”, the thermally conductive and electrically insulating substrate provided by the present disclosure can be formed into a structure that has a plurality of chips arranged thereon, such that a utilization rate of the thermally conductive and electrically insulating substrate can be effectively increased.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a thermally conductive and electrically insulating substrate having a chip arranged thereon according to a related art;

FIG. 2 is a schematic side view of a thermally conductive and electrically insulating substrate according to a first embodiment of the present disclosure;

FIG. 3 is a schematic side view of the thermally conductive and electrically insulating substrate according to a second embodiment of the present disclosure;

FIG. 4 is a schematic side view of the thermally conductive and electrically insulating substrate according to a third embodiment of the present disclosure;

FIG. 5 is a schematic side view of the thermally conductive and electrically insulating substrate having a chip arranged thereon according to a fourth embodiment of the present disclosure;

FIG. 6 is a schematic side view of the thermally conductive and electrically insulating substrate according to a fifth embodiment of the present disclosure;

FIG. 7 is a schematic side view of the thermally conductive and electrically insulating substrate according to a sixth embodiment of the present disclosure;

FIG. 8 is a schematic side view of the thermally conductive and electrically insulating substrate according to a seventh embodiment of the present disclosure;

FIG. 9 is a schematic side view of the thermally conductive and electrically insulating substrate according to an eighth embodiment of the present disclosure;

FIG. 10 is a schematic side view of the thermally conductive and electrically insulating substrate having a chip arranged thereon according to a ninth embodiment of the present disclosure;

FIG. 11 is a schematic side view of the thermally conductive and electrically insulating substrate according to a tenth embodiment of the present disclosure;

FIG. 12 is a schematic side view of the thermally conductive and electrically insulating substrate according to an eleventh embodiment of the present disclosure;

FIG. 13 is a schematic side view of the thermally conductive and electrically insulating substrate according to a twelfth embodiment of the present disclosure; and

FIG. 14 is a schematic side view of the thermally conductive and electrically insulating substrate according to a thirteenth embodiment of the present disclosure.

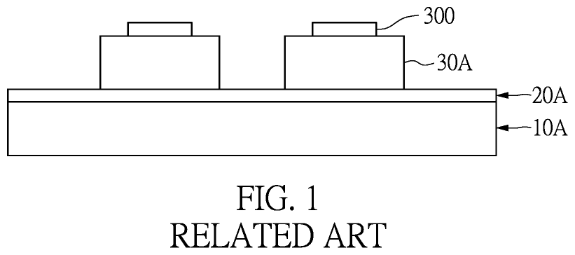

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way.

Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### EMBODIMENTS

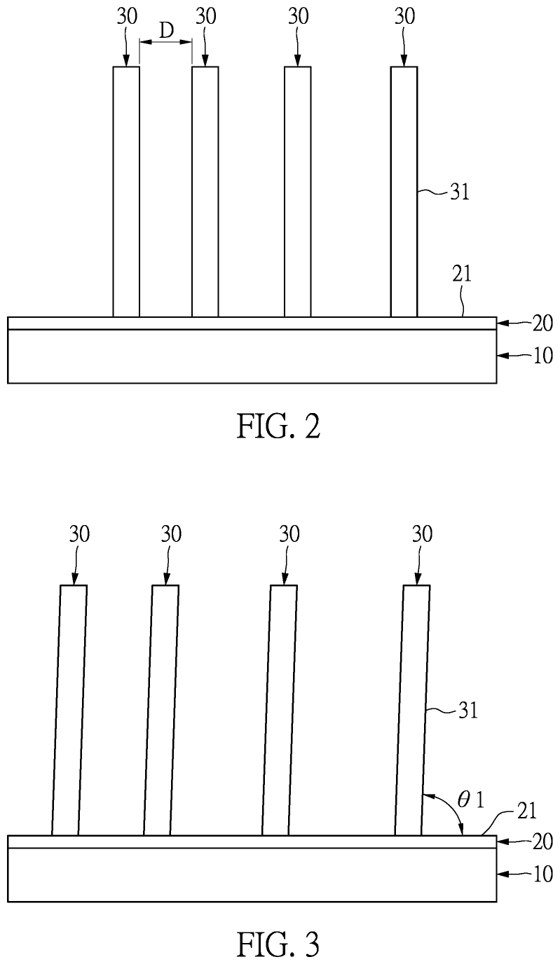

Referring to FIG. 2, the present disclosure provides a thermally conductive and electrically insulating substrate. As shown in the figure, the thermally conductive and electrically insulating substrate of the present disclosure includes a thermally conductive base 10, an electrically insulating layer 20, and one or more metal sheets 30.

As mentioned above, the electrically insulating layer 20 is disposed on the thermally conductive base 10. The thermally conductive base 10 can be an aluminum heat sink or a metal substrate having heat dissipation properties, but is not limited thereto. In the present embodiment, the electrically insulating layer 20 can be made of a high-binding polymer material, such as epoxy resin, so as to increase a binding property. In addition, the electrically insulating layer 20 can also include a ceramic filler, so as to increase a thermal conductivity.

In the present embodiment, the one or more metal sheets 30 are disposed on the electrically insulating layer 20, and each of the metal sheets 30 can be allowed to have one or more chips (referring to chips 300 of FIG. 5) arranged thereon. Moreover, in the present embodiment, at least a part of a surface of the metal sheet 30 (i.e., an engaging surface 31 of the metal sheet 30) where the metal sheet 30 is allowed to be engaged with the chip is not parallel to a surface of the electrically insulating layer 20 (i.e., a mating surface 21 of the electrically insulating layer 20) where the electrically insulating layer 20 is mated with the metal sheet 30.

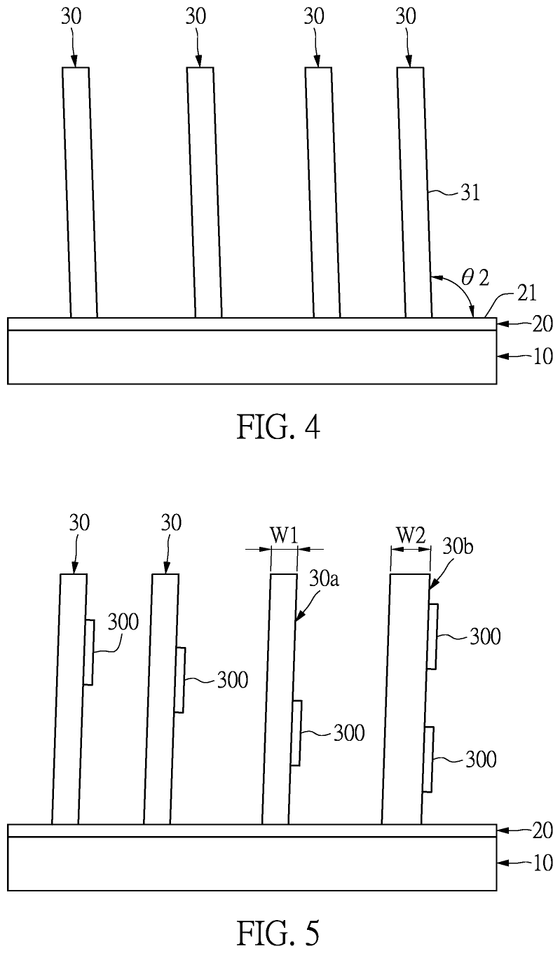

More specifically, the surface of the metal sheet 30 where the metal sheet 30 is allowed to be engaged with the chip and the surface of the electrically insulating layer 20 (the mating surface 21) can be perpendicular to each other, or have an acute angle or an obtuse angle therebetween. Referring to FIG. 3, the surface of the metal sheet 30 where the metal sheet 30 is allowed to be engaged with the chip and the surface of the electrically insulating layer 20 (the mating surface 21) can have an acute included angle θ1 therebetween. Referring to FIG. 4, the surface of the metal sheet 30 where the metal sheet 30 is allowed to be engaged with the chip and the surface of the electrically insulating layer 20 (the mating surface 21) can have an obtuse included angle θ2 therebetween. In this way, the thermally conductive and electrically insulating substrate of the present disclosure can be formed into a structure that has a plurality of chips arranged thereon, such that a utilization rate of the thermally conductive and electrically insulating substrate can be effectively increased. In addition, the metal sheet 30 can be submerged in a working fluid (a non-electrically conductive cooling fluid), so as to achieve better heat dissipation by immersion cooling.

Furthermore, distances between the metal sheets 30 can also be adjusted according to requirements. That is to say, distances D between the metal sheets 30 can be the same or different. In addition, a width of each of the metal sheets 30 can be adjusted according to requirements. That is to say, the width of each of the metal sheets 30 can be the same or different. Moreover, referring also to the thermally conductive and electrically insulating substrate shown in FIG. 5, one metal sheet (a first metal sheet 30a) exemplarily has one of the chips 300 (e.g., an insulated gate bipolar transistor (IGBT) chip) arranged thereon, and another metal sheet (a second metal sheet 30b) exemplarily has two of the chips 300 arranged thereon. That is to say, a quantity of the chips arranged on the second metal sheet 30b is greater than a quantity of the chips arranged on the first metal sheet 30a, so that heat generation of the second metal sheet 30b is greater than heat generation of the first metal sheet 30a. Accordingly, a width W2 of the second metal sheet 30b is greater than a width W1 of the first metal sheet 30a, so as to increase uniformity of heat dissipation and heat transferring efficiency. In addition, the width W1 of the first metal sheet 30a is smaller than the width W2 of the second metal sheet 30b, such that a cost of metal materials can be reduced.

Moreover, the chips 300 and lead wires (not shown in the figures) can be arranged in advance on the metal sheet 30 by soldering, so that the metal sheets 30 with the pre-soldered chips 300 and the pre-soldered lead wires are disposed on the electrically insulating layer 20 at intervals, thereby effectively speeding up a production process.

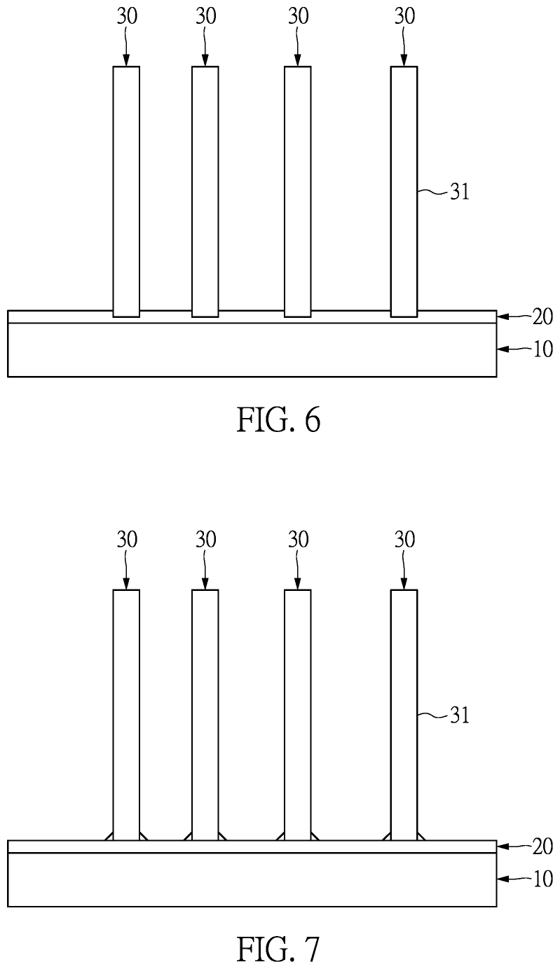

In addition, one end of the metal sheet 30 can be engaged with the surface of the electrically insulating layer 20, be inserted into the electrically insulating layer 20, or be embedded by the electrically insulating layer 20. Referring to FIG. 6, the one end of the metal sheet 30 is inserted into the electrically insulating layer 20. Referring to FIG. 7, the one end of the metal sheet 30 is embedded by the electrically insulating layer 20.

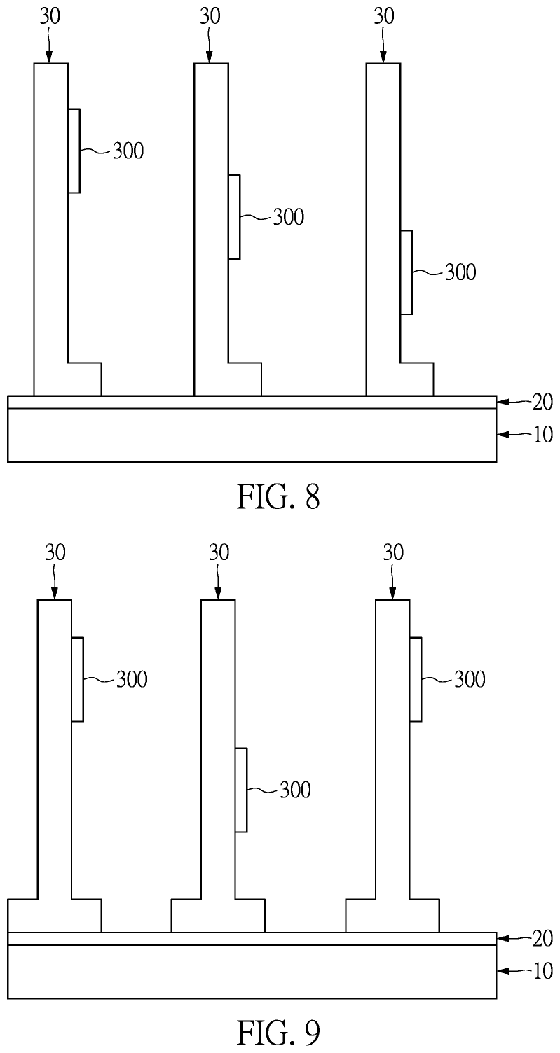

Moreover, the one end of the metal sheet 30 can be in an L-shape and be engaged with the surface of the electrically insulating layer 20, or be in an inverted T-shape and be engaged with the surface of the electrically insulating layer 20. Referring to FIG. 8, the one end of the metal sheet 30 is in the L-shape and engaged with the surface of the electrically insulating layer 20. Referring to FIG. 9, the one end of the metal sheet 30 is in the inverted T-shape and engaged with the surface of the electrically insulating layer 20.

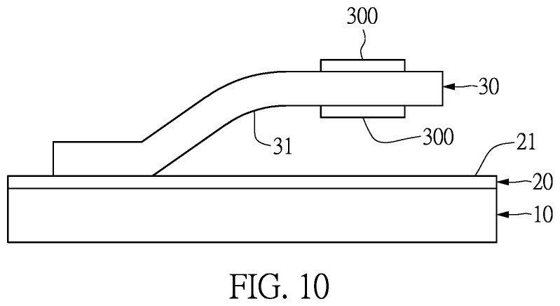

In addition, referring to FIG. 10, at least a part (an inclined part of the engaging surface 31) of the surface of the metal sheet 30 where the metal sheet 30 is engaged with the chip 300 (i.e., the engaging surface 31 of the metal sheet 30) is not parallel to the surface of the electrically insulating layer 20 (i.e., the mating surface 21 of the electrically insulating layer 20) where the electrically insulating layer 20 is mated with the metal sheet 30.

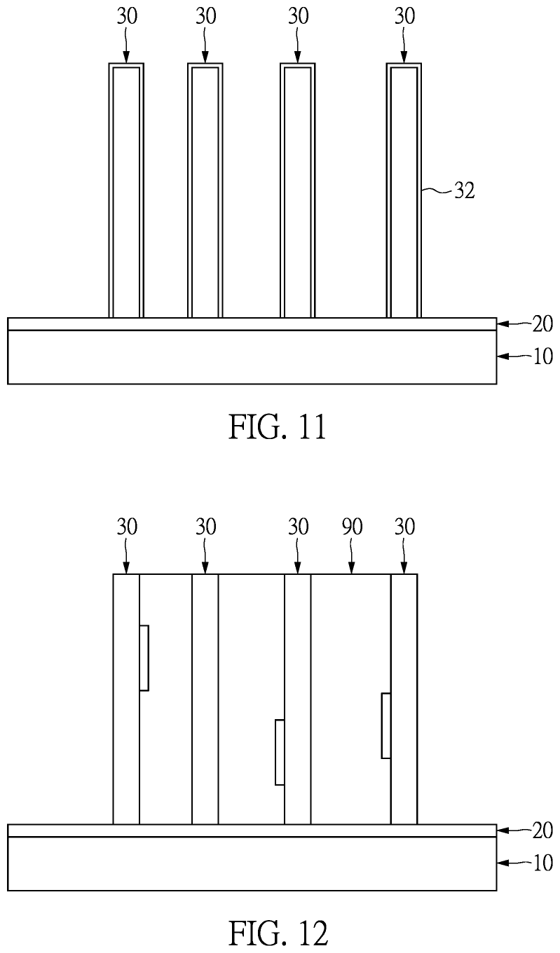

Referring to FIG. 11, a thermally conductive layer 32 (such as graphite or grapheme) can also be formed on the surface of the metal sheet 30, such that heat can be evenly conducted along both directions, and the uniformity of heat dissipation and the heat transferring efficiency can be increased. In another embodiment, the metal sheet 30 can also be made of a non-metal with good thermal conductivity, such as graphite. The metal sheet 30 can also be a vapor chamber or a heat pipe.

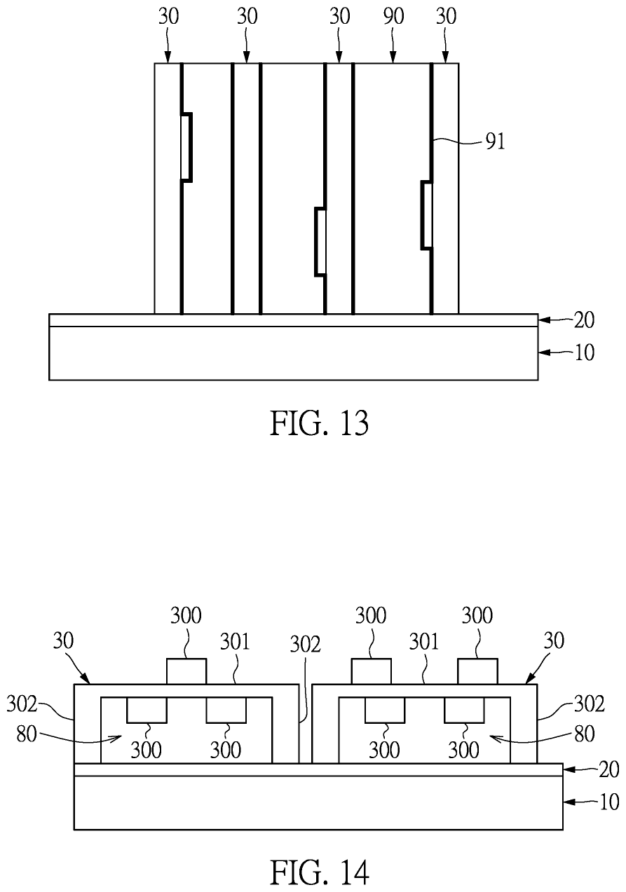

Referring to FIG. 12, the metal sheets 30 can have an electrically insulating mold 90 arranged therebetween, so that the metal sheets 30 can be better positioned and have different distances therebetween. The electrically insulating mold 90 can be removed or not removed. In a case where the electrically insulating mold 90 does not need to be removed, the electrically insulating mold 90 can be made of the high-binding polymer material, such as epoxy resin, so as to increase the binding property and therefore prevent separation. In addition, referring to FIG. 13, the electrically insulating mold 90 can also be made of a non-metallic material with low electric conductivity, such as polytetrafluoroehtylene. The electrically insulating mold 90 can also have a polymer layer 91 attached to a surface of the electrically insulating mold 90, and the polymeric layer 91 is made of the high-binding polymer material.

Referring to FIG. 14, the one or more metal sheets 30 are disposed on the electrically insulating layer 20, and the metal sheet 30 has the one or more chips 300 arranged thereon. In the present embodiment, the metal sheet 30 is bent downwardly to form a hollow structure 80 between the metal sheet 30 and the electrically insulating layer 20. Moreover, in the present embodiment, two of the metal sheets 30 are bent downwardly, so that there are two hollow structures 80 formed between the two of the metal sheets 30 and the electrically insulating layer 20. In addition, the surface of the metal sheet 30 where the metal sheet 30 is engaged with the chip 300 is parallel to the surface of the electrically insulating layer 20 where the electrically insulating layer 20 is mated with the metal sheet 30.

Specifically speaking, the metal sheet 30 is formed to have a chip engaging portion 301 and two bending portions 302 that are formed by bending downwardly from both ends of the chip engaging portion 301. A top surface and a bottom surface of the chip engaging portion 301 can each be allowed to be engaged with the one or more chips 300. The bending portion 302 is mated with the surface of the electrically insulating layer 20. The top surface and the bottom surface of the chip engaging portion 301 are parallel to the surface of the electrically insulating layer 20.

Furthermore, in the present embodiment, one of the chips 300 is exemplarily disposed on the top surface of one of the chip engaging portions 301, and two of the chips 300 are exemplarily disposed on the bottom surface of the one of the chip engaging portions 301. That is to say, a quantity of the chips disposed on the bottom surface of the chip engaging portion 301 is greater than a quantity of the chips disposed on the top surface of the chip engaging portion 301. Accordingly, a flowing working fluid (such as the non-electrically conductive cooling fluid) can be further arranged in the hollow structure 80, so that a higher amount of heat generated by the larger quantity of the chips disposed on the bottom surface of the chip engaging portion 301 can be conducted away more quickly.

In addition, the present disclosure also provides a process for manufacturing a thermally conductive and electrically insulating substrate, which includes the following steps:

(a) providing a mold;

(b) placing one or more metal sheets in the mold;

(c) pressing the mold and the one or more metal sheets onto a thermally conductive base that has an electrically insulating layer formed on a surface; and

(d) removing the mold.

Accordingly, the surface of the metal sheet where the metal sheet is allowed to be engaged with the chip is not parallel to the surface of the electrically insulating layer where the electrically insulating layer is mated with the metal sheet. In addition, a surface of the mold can have a separation layer, such as gold foil, so that the mold can be easily separated from the electrically insulating layer after the pressing process. In addition, the surface of the metal sheet can have pre-soldered chips and lead wires. In addition, the metal sheet can be encapsulated by the polymer material, and then pressed onto the electrically insulating layer. In addition, the metal sheet with the pre-soldered chips and lead wires can also be encapsulated by the polymeric material, and then pressed onto the electrically insulating layer.

### BENEFICIAL EFFECTS OF THE EMBODIMENTS

In conclusion, by virtue of “at least a part of the surface of the metal sheet where the metal sheet is allowed to be engaged with the chip being not parallel to the surface of the electrically insulating layer where the electrically insulating layer is mated with the metal sheet”, the thermally conductive and electrically insulating substrate provided by the present disclosure can be formed into a structure that has a quantity of chips arranged thereon, such that the utilization rate of the thermally conductive and electrically insulating substrate can be effectively increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A thermally conductive and electrically insulating substrate, comprising: a thermally conductive base, an electrically insulating layer, and one or more metal sheets, wherein the electrically insulating layer is disposed on the thermally conductive base and the one or more metal sheets are disposed on the electrically insulating layer; wherein the metal sheet is allowed to have one or more chips arranged thereon, and at least a part of a surface of the metal sheet where the metal sheet is allowed to be engaged with the chip is not parallel to a surface of the electrically insulating layer where the electrically insulating layer is mated with the metal sheet.

2. The thermally conductive and electrically insulating substrate according to claim 1, wherein the surface of the metal sheet where the metal sheet is allowed to be engaged with the chip and the surface of the electrically insulating layer where the electrically insulating layer is mated with the metal sheet are perpendicular to each other.

3. The thermally conductive and electrically insulating substrate according to claim 1, wherein the surface of the metal sheet where the metal sheet is allowed to be engaged with the chip and the surface of the electrically insulating layer where the electrically insulating layer is mated with the metal sheet have an acute included angle therebetween.

4. The thermally conductive and electrically insulating substrate according to claim 1, wherein the surface of the metal sheet where the metal sheet is allowed to be engaged with the chip and the surface of the electrically insulating layer where the electrically insulating layer is mated with the metal sheet have an obtuse included angle therebetween.

5. The thermally conductive and electrically insulating substrate according to claim 1, wherein a width of a first metal sheet of the metal sheets is different from a width of a second metal sheet of the metal sheets, and a quantity of the chips allowed to be disposed on the second metal sheet is greater than a quantity of the chips allowed to be disposed on the first metal sheet.

6. The thermally conductive and electrically insulating substrate according to claim 1, wherein distances between the metal sheets are different.

7. The thermally conductive and electrically insulating substrate according to claim 1, wherein one end of the metal sheet is inserted into the electrically insulating layer.

8. The thermally conductive and electrically insulating substrate according to claim 1, wherein one end of the metal sheet is embedded within the electrically insulating layer.

9. The thermally conductive and electrically insulating substrate according to claim 1, wherein one end of the metal sheet is in an L-shape and is engaged with the electrically insulating layer.

10. The thermally conductive and electrically insulating substrate according to claim 1, wherein one end of the metal sheet is in an inverted T-shape and is engaged with the electrically insulating layer.

11. The thermally conductive and electrically insulating substrate according to claim 1, wherein a thermally conductive layer is formed on the surface of the metal sheet, and the thermally conductive layer is made of graphite or graphene.

12. The thermally conductive and electrically insulating substrate according to claim 1, wherein the metal sheets that are adjacent to each other have an electrically insulating mold arranged therebetween.

13. The thermally conductive and electrically insulating substrate according to claim 12, wherein the electrically insulating mold is made of a high-binding polymer material.

14. The thermally conductive and electrically insulating substrate according to claim 12, wherein the electrically insulating mold is made of a non-metallic material with low electrical conductivity, and the electrically insulating mold has a polymer layer that is attached to a surface of the electrically insulating mold.

15. A thermally conductive and electrically insulating substrate, comprising: a thermally conductive base, an electrically insulating layer, and one or more metal sheets, wherein the electrically insulating layer is disposed on the thermally conductive base, and the one or more metal sheets are disposed on the electrically insulating layer; wherein the metal sheet has at least one chip arranged thereon, and at least a part of a surface of the metal sheet where the metal sheet is engaged with the chip is not parallel to a surface of the electrically insulating layer where the electrically insulating layer is mated with the metal sheet.

16. The thermally conductive and electrically insulating substrate according to claim 15, wherein the metal sheet is a metal sheet with pre-soldered chips and lead wires.

17. The thermally conductive and electrically insulating substrate according to claim 15, wherein a width of a first metal sheet of the metal sheets is different from a width of a second metal sheet of the metal sheets, and a quantity of the chips disposed on the second metal sheet is greater than a quantity of the chips disposed on the first metal sheet.

18. The thermally conductive and electrically insulating substrate according to claim 15, wherein the metal sheets that are adjacent to each other have an electrically insulating mold arranged therebetween.

19. A thermally conductive and electrically insulating substrate, comprising: a thermally conductive base, an electrically insulating layer, and one or more metal sheets, wherein the electrically insulating layer is disposed on the thermally conductive base, and the one or more metal sheets are disposed on the electrically insulating layer; wherein the metal sheet is bent downwardly, so that a hollow structure is formed between the metal sheet and the electrically insulating layer; wherein the metal sheet has one or more chips arranged thereon, and a surface of the metal sheet where the metal sheet is engaged with the chip is parallel to a surface of the electrically insulating layer where the electrically insulating layer is mated with the metal sheet.

20. The thermally conductive and electrically insulating substrate according to claim 19, wherein the hollow structure has a flowing working fluid therein.
